(19) United States
(12) Patent Application Publication
(10) Pub. No.: US 2024/0431077 A1
(43) Pub. Date: Dec. 26, 2024

(54) THERMAL INTERFACE APPLIQUES

(71) Applicant: Liquid Wire Inc., Portland, OR (US)

(72) Inventors: Mark William Ronay, Portland, OR (US); Michael Adventure Hopkins, Portland, OR (US); Michael Jasper Wallans, Portland, OR (US)

(73) Assignee: Liquid Wire Inc., Portland, OR (US)

(21) Appl. No.: 18/823,089

(22) Filed: Sep. 3, 2024

Related U.S. Application Data
(63) Continuation of application No. PCT/US2023/061264, filed on Jan. 25, 2023.
(60) Provisional application No. 63/268,795, filed on Mar. 2, 2022.

(51) Int. Cl. H05K 7/20

(52) U.S. Cl. CPC H05K 7/20463

(57) ABSTRACT

A thermal interface applique and system includes a containment structure and conductive gel. The containment structure has an adhesive property and a first thermal coefficient. The conductive gel is configured to thermally couple a heat source to a heatsink. The adhesive property of the containment structure is configured to adhere at least one of the heat source and the heatsink to the containment structure

### CROSS REFERENCE TO RELATED APPLICATIONS

This patent application is a continuation of PCT Application No. PCT/US2023/061264, which claims the benefit of U.S. Provisional Patent Application No. 63/268,795, filed Mar. 2, 2022, both of which are incorporated by reference in their entirety.

### BACKGROUND

Certain electronic components may generate excess heat when operating. For instance, current loss within a component may manifest as waste heat. Conventionally, the waste heat may be allowed to radiate from the component itself or be removed with a heatsink or other device to facilitate the removal of the waste heat from the electronic component.

### BRIEF DESCRIPTION OF THE DRAWINGS

To easily identify the discussion of any particular element or act, the most significant digit or digits in a reference number refer to the figure number in which that element is first introduced.

FIG. 1 is an exploded view of an electronic system including an electronic component thermally coupled to a heatsink with a thermal interface applique, in an example embodiment.

FIG. 2 is an exploded view of an alternative electronic system, in an example embodiment.

FIG. 3 shows the thermal interface applique, in an example embodiment.

FIG. 4 shows a thermal interface applique including multiple rectangular openings in the containment structure, in an example embodiment.

FIG. 5 shows a thermal interface applique including openings of different shapes, in an example embodiment.

FIG. 6 shows a thermal interface applique including multiple circular openings, in an example embodiment.

FIG. 7 illustrates a sheet of thermal interface appliques, in an example embodiment.

FIG. 8A illustrates a roll of thermal interface appliques, in an example embodiment.

FIG. 8B illustrates a side profile of a portion of the roll, in an example embodiment.

### DETAILED DESCRIPTION

Example methods and systems are directed to a thermal interface applique, system, and method. Examples merely typify possible variations. Unless explicitly stated otherwise, components and functions are optional and may be combined or subdivided, and operations may vary in sequence or be combined or subdivided. In the following description, for purposes of explanation, numerous specific details are set forth to provide a thorough understanding of example embodiments. It will be evident to one skilled in the art, however, that the present subject matter may be practiced without these specific details.

While heatsinks and the like may be effective in radiating waste heat from an electronic component, thermal transfer of heat from the electronic component to the heatsink may be dependent in part on a thermal interface between the electronic component and the heatsink. A conventional chip package may include a ceramic or other material to enclose the chip within the package, but such materials may not form an efficient thermal interface with a metal heatsink.

Certain attempts have been made to provide efficient thermal interfaces, but such attempts are generally based on silicone or other similar material, which, while more efficient than air, is far less efficient than metal-based conductors. For instance, silicone may have a thermal coefficient from one (1) to four (4) Watts per meter Kelvin (W/mK)). Other attempts have been based on the deposition of a liquid phase alloy between the electronic component and the heatsink. However, such liquid phase alloys carry the risk of migration away from the original deposition of the alloy which, given the alloy is conductive, carries the risk of creating short circuits elsewhere in the system, including with the electronic component itself. Moreover, certain materials from which heatsinks are conventionally made, such as aluminum, may be subject to being dissolved by the liquid phase alloy.

A thermal interface based on conductive gel has been developed to provide a high thermal coefficient with a reduced risk of migration of the material from examples that have utilized a liquid phase alloy. Such conductive gels may have a thermal coefficient approximately ten (10) times or more higher than silicone-based, e.g., approximately ten (10) W/mK to one hundred (100) W/mK. The inclusion of carbon allotrope additives in a nano-or micro-particle format in the conductive gel may further increase the thermal coefficient of the conductive gel. The conductive gel is chemically stable, adheres to a variety of materials, and has a lower risk of migration than, e.g., liquid phase alloys. Consequently, the conductive gel may act as a highly efficient and deformable medium for establishing a thermal coupling between the two components being attached, greatly improving the cooling rate of an electronic component. The conductive gel may allow for more computing or processing power, or power handling capabilities depending on the type of electronic component, e.g., a processor, that is being attached to another component, e.g., a heatsink.

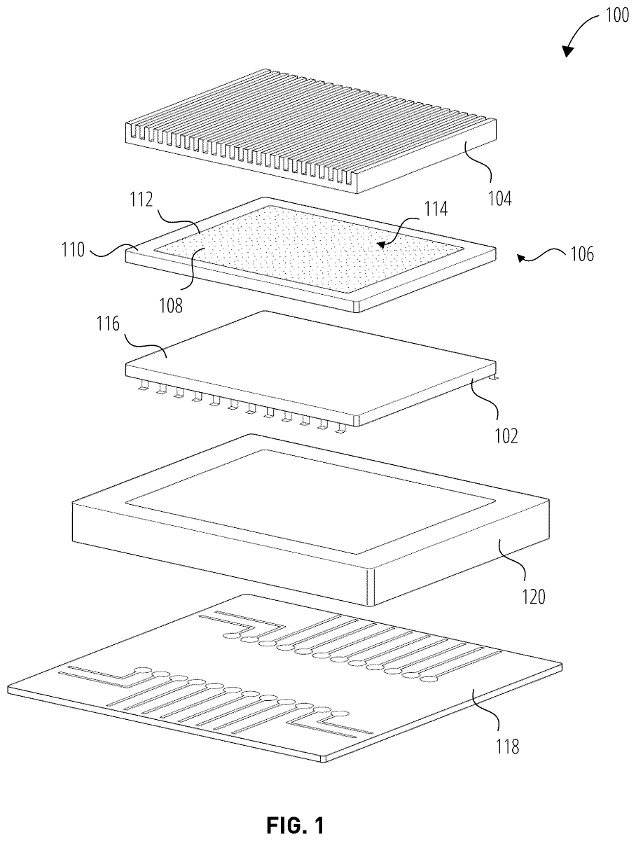

FIG. 1 is an exploded view of an electronic system 100 including an electronic component 102 thermally coupled to another component, such as a heatsink 104 with a thermal interface applique 106, in an example embodiment. The electronic component 102 is a conventional chip package, but it is to be recognized and understood that the principles disclosed herein may apply to any suitable electronic component that has been or may be developed. Similarly, the heatsink 104 is a conventional metallic heatsink known in the art, but the principles disclosed herein may be applied to any device that may facilitate the removal of waste heat from an electronic component 102 through a thermal interface that has been or may be developed. As such, while the electronic component 102 is described and illustrated specifically, the principles disclosed herein are equally applicable to any general heat source. Further, while an electronics heatsink is described and illustrated specifically, the principles disclosed herein are equally appliable to any heatsink.

The thermal interface applique 106 includes conductive gel 108 and a containment structure 110 configured to secure the conductive gel 108 in a predetermined configuration. Such a predetermined configuration may be the rectangular configuration as illustrated in FIG. 1, or may be any of the various alternative configurations illustrated herein. The conductive gel 108 may be the conductive gel disclosed herein and/or may be adapted with carbon allotrope additives (some of which, such as diamond, may have a thermal coefficient of 1,000 W/mK to 2,000 W/mK or more) in a nano-or micro-particle format which may improve the thermal coefficient of the conductive gel 108. In an example, the conductive gel 108 may include as much as seventy (70) percent carbon allotrope, which may increase the thermal coefficient of the conductive gel 108 to more than forty (40) W/mK and up to one hundred (100) W/mK. In various experiments of an example of the conductive gel, the conductive gel had a thermal conductivity at twenty-one (21) degrees Celsius of 10.65 W/mK, 10.63 W/mK, 10.56 W/mK, 10.60 W/mK, and 10.59 W/mK. The conductive gel had a mean thermal conductivity of 10.61 W/mK, a standard deviation of 0.03, and a relative standard deviation (RSD) of 0.27.

The conductive gel 108 may be completely surrounded by the containment structure 110, e.g., an interior perimeter 112 of the containment structure 110 fully surrounds the conductive gel 108 and prevent or significantly inhibit the conductive gel 108 from migrating laterally from the containment structure 110. The interior perimeter 112 defines an opening 114 in the containment structure 110 that corresponds to a form factor of the electronic component 102 such that a surface area of the conductive gel 108 is similar to a surface area of a major surface 116 of the electronic component 102. Consequently, in an example, a particular thermal interface applique 106 may be designed for any electronic component 102 having the same form factor, with different sizes of thermal interface applique 106 made for different form factors of different electronic components 102.

In various examples, the surface area of the conductive gel 108 may be at least fifty (50) percent that of the surface area of the major surface 116 and may be up to one hundred (100) percent of the surface area of the major surface 116. The size of the opening 114 may be optimized to maximize the transfer of heat from the electronic component 102 to the heatsink 104 while still providing adequate containment for the conductive gel 108. Consequently, as disclosed herein, the number and shapes of openings 114 may vary in alternative examples of the containment structure 110.

The containment structure 110 may be formed of any of a variety of suitable materials, including but not limited to thermoplastic polyurethane (TPU) film, B-stage resin film, or any other suitable film or material that can contain the conductive gel 108. Additionally or alternatively, a C-stage resin film, an adhesive, a thermoset epoxy-based film may be utilized, where such materials have an adhesive property. Further, combinations of materials may be utilized as the containment structure 110, e.g., a polyimide flex PCB-type sheet or film material with an adhesive film applied to attachment surfaces. Moreover, the material of the containment structure 110 may provide bonding between the electronic component 102 and the heatsink 104. Thus, in such an example, the containment structure 110 may be secured to each of the electronic component 102 and heatsink 104, with each of the electronic component 102 and heatsink 104 providing further containment for the conductive gel 108 to prevent or inhibit migration. In various examples, the thermal interface applique 106 may be applied to the electronic component 102 alone, or to the electronic component 102 and an additional structure related to the electronic component 102, such as an electronic component surround 120 that may increase or maximize the cooling area available for the electronic component 102 while allowing adequate bond strength for the heatsink 104. The electronic component surround 120 may also allows for a larger heatsink 104 than may be possible or practical for the electronic component 102 without the electronic component surround 120.

The bonding area of the thermal interface applique 106 may be understood to be the surface area of the containment structure 110. The cooling area of the thermal interface applique 106 may be understood to be the surface area of the conductive gel 108. The cooling area of the thermal interface applique 106 is optimally as large a percentage of the total surface area of the thermal interface applique 106, e.g., the cooling area plus the bonding area, as possible, and the bonding area may be designed to be just large enough to prevent or sufficiently inhibit migration of the conductive gel 108 from the top surface of the electronic component. In an example, the bonding area extends in at least approximately one (1) millimeter from an edge of the electronic component 102, up to about three (3) mm. In such examples, the surface area of the electronic component surround 120 may be the same as the bonding area plus the overlap onto the electronic component.

In various examples, the electronic component 102 and/or heatsink 104 may have uneven surfaces, including deliberate unevenness or imperfections. In various examples, the thermal interface applique 106 may have a thickness and flexibility that allows the thermal interface applique 106 to take up such imperfections without breaking bonding between the thermal interface applique 106 and the electronic component 102 and/or heatsink 104. In an example, the thermal interface applique 106 has a thickness of 0.004 inches, but it is to be recognized and understood that any suitable thickness may be implemented that still provides sufficient thermal conductivity by the conductive gel 108 between the electronic component 102 and the heatsink 104. In some examples, the thermal interface applique 106 may have a thickness in the range of about 0.002 inches to about 0.100 inches. Larger applique thicknesses in combination with a soft containment material characteristic may be particularly beneficial for use on surfaces that are coarse or uneven.

In various examples, the thermal interface applique 106 may be applied to and bonded with one or both of the electronic component 102 and heatsink 104 according to any of a variety of methods. In an example, the containment structure 110 may be melted prior to or after being applied to the electronic component 102 and/or heatsink 104. In an example, the containment structure 110 may be cured under pressure and/or heat. Melting may allow the containment structure 110 to flow into surface variations of the electronic component 102 and/or heatsink 104. Cooling and/or curing the containment structure 110 may create a seal between the containment structure 110 and the electronic component 102 and/or heatsink 104 that may inhibit or prevent migration of the conductive gel 108. Curing operations may be carried out, e.g, through the use of heat or other exemplary methods such as exposure to UV light, moisture, gases or combinations thereof. Consequently, because the conductive gel 108 and containment structure 110 are deformable and/or conformable, the thermal interface applique 106 may be applicable to and adaptable to any of a variety of circumstances involving different electronic components 102 and/or heatsinks 104.

In various examples, the thermal interface applique 106 may optionally additionally include a thin film or other thin isolating material on one or both major surfaces of the thermal interface applique 106. In various examples, the thin film may be made from any conventional thermal interface material and may optionally be included in the electronic system 100 or may be removed prior to applying the thermal interface applique 106 to the electronic component 102 and/or heatsink 104. Additionally or alternatively, the heatsink 104 may be anodized or coated at least at the interface with the thermal interface applique 106, e.g., via physical vapor deposition, electroplating, etc., with a material that is non-dissolvable in liquid metal. The material may be metal, carbon, industrial diamond, or any other suitable material. The metal may include but not be limited to copper, gold, silver, etc., and may optionally be finished with encapsulation, potting, etc., after attachment to the heatsink 104.

In various examples, the conductive gel 108 comes prepositioned in the containment structure 110, e.g, as a result of the manufacturing process, and a user of the thermal interface applique 106 simply applies the thermal interface applique 106 to the electronic component 102 and/or the heatsink 104 fully constituted. In an alternative example, the conductive gel 108 may be inserted into the opening 114 after the thermal interface applique 106 is applied to one or more of the other components 102, 104. In various examples and circumstances, all of the conductive gel 108 may be inserted after initial application of the thermal interface applique to another component 102, 104. In other examples and circumstances, some of the conductive gel 108 may already be present in the opening 114 before application and the remainder of the conductive gel 108 may be added after application, e.g., the conductive gel 108 may be “topped up” or otherwise filled out after application.

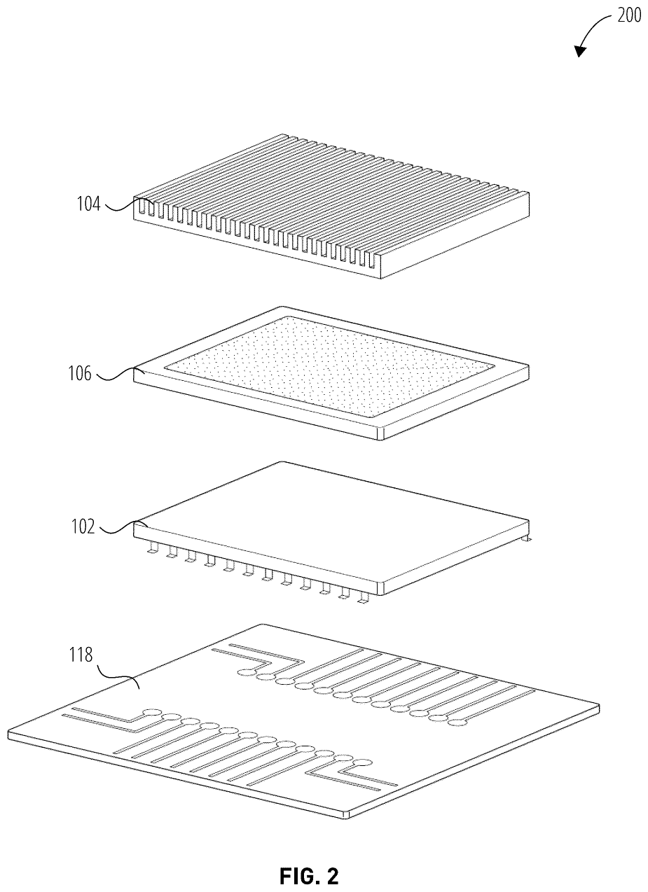

FIG. 2 is an exploded view of an alternative electronic system 200, in an example embodiment. The electronic system 200 includes the electronic component 102, heatsink 104, thermal interface applique 106, and PCB 118. But the electronic system 200 does not include the electronic component surround 120. Consequently, optionally in such an example, the thermal interface applique 106 may have a cooling area at least fifty (50) percent that of the total surface area of the thermal interface applique 106 and, in various examples, at least seventy (70) percent that of the total surface area of the thermal interface applique 106. Consequently, in contrast to the example of the electronic system 100 of FIG. 1, the thermal interface applique 106 as optionally implemented in FIG. 2 may have a smaller percentage cooling area, as the bonding area of the thermal interface applique 106 of FIG. 1 may optionally be larger to bond with the heat sink 104.

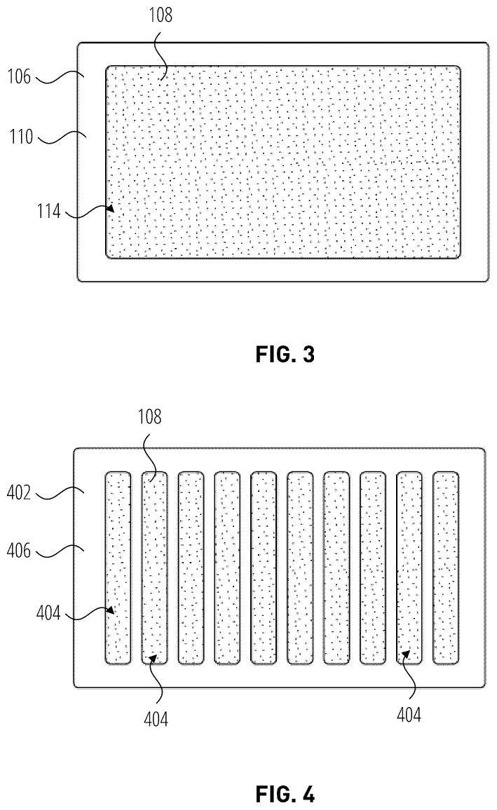

FIG. 3-FIG. 6 are examples of thermal interface appliques, in various example embodiments. The various examples provide detail images of major surfaces of the thermal interface appliques to illustrate differences in the shapes of the opening/openings and resultant conductive gel 108. FIG. 3-FIG. 6 thus illustrate various shapes that may be adapted to various sizes or proportions, as appropriate.

FIG. 3 shows the thermal interface applique 106 illustrated in FIG. 1. The thermal interface applique 106 includes one rectangular opening 114 in the containment structure 110, resulting in the conductive gel 108 taking a single rectangular shape.

FIG. 4 shows a thermal interface applique 402 including multiple rectangular openings 404 in the containment structure 406. The thermal interface applique 402 thus results in the conductive gel 108 taking multiple rectangular shapes separated from one another by portions of the containment structure 406.

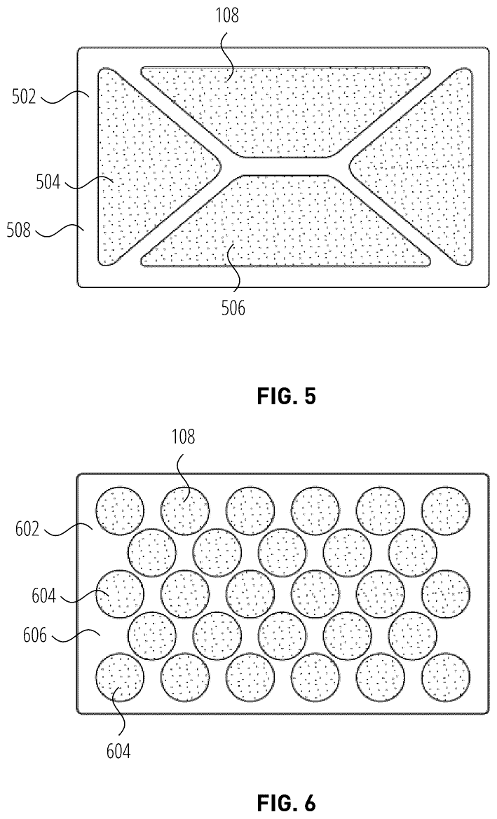

FIG. 5 shows a thermal interface applique 502 including openings of different shapes. In particular, the thermal interface applique 502 includes triangular openings 504 and trapezoidal openings 506 separated from one another by portions of the containment structure 508. Thus, the thermal interface applique 502 generally forms the conductive gel 108 into triangular and trapezoidal shapes separated by portions of the containment structure 508.

FIG. 6 shows a thermal interface applique 602 including multiple circular openings 604. The thermal interface applique 602 thus results in the conductive gel 108 taking multiple circular shapes separated from one another by portions of the containment structure 606.

The various example thermal interface appliques illustrated herein are provided by way of example and not limitation and any suitable number and geometry of opening or openings is contemplated, including but not limited to a square, an ellipse, an oval, a diamond, a parallelogram, a pentagon, a hexagon, an octagon, etc. Moreover, while each thermal interface applique is shown with openings in regular shapes, irregularly-shaped openings are contemplated as well, with either all of the openings irregularly shaped or in conjunction with regular-shaped openings, and/or any regular geometric or irregular shape with some combination of linear and/or curved perimeter edges. The shape of the openings may be based on the shape of one or more characteristic features of the electronic component 102 and/or heatsink 104 that may be coupled to the thermal interface applique.

Regardless of the shape, a given thermal interface applique may have a major dimension, e.g., a width, a length, a diameter, or some other characteristic dimension defining the largest linear measure of the thermal interface applique. In various examples, the major dimension may have a minimum value of at least about 0.1 inches whereas the thickness of the thermal interface applique, in some examples, may be approximately 0.002-0.020 inches per layer. Thus, for the smallest single layer thermal interface applique contemplated in this particular example, there is at least a 5:1 ratio between the characteristic dimension and the thickness of the thermal interface applique. In other examples, the thermal interface applique may have a characteristic dimension that is at least 0.5 inches, and each layer may have a thickness between approximately 0.002 and 0.020 inches yielding a minimum ratio of 25:1 for a single layer thermal interface applique. Should more than one substrate layer be desired for a particular thermal interface applique configuration, each layer may be less than the maximum layer thicknesses contemplated above. It has been shown that good contact and adequate structural adhesion between a circuit and a thermal interface applique may be obtained, for example, with layer thicknesses between about 0.003 to about 0.006 inches in both single and multi-layer configurations. Thicker or thinner layer thicknesses may be used should the requirements of a particular application require them. For example, a thicker layer may provide increased thermal isolation between an electronic component and the circuit. In another example, a thicker or thinner layer may be used to meet physical requirements for the overall thickness of a circuit assembly, e.g., to ensure that the assembly fits within an enclosure or other structure having certain limiting dimensions, such an internal height dimension which limits the overall thickness of any assembly that could be contained therein.

Thermal interface applique as contemplated by the principles taught herein may be made using the techniques, methods, materials and structures taught in U.S. patent application Ser. No. 16/548,379 entitled “Structures with deformable conductors” and filed on Aug. 22, 2019 and which is hereby incorporated by reference in its entirety.

It may be appreciated that features of a thermal interface applique may comprise conductive gel or other deformable conductor and may optionally or alternatively comprise a conventional conductor such as, e.g.: copper, gold or silver foil and/or wires. For example, certain features may have a configuration as described in U.S. Provisional Patent Application No. 63/201,902 entitled FLEXIBLE HIGH-POWER ELECTRONICS BUS filed on May 5, 2021 and which is hereby incorporated by reference in its entirety.

The containment structure 110 and/or other substrate material may include one or more of a wide variety of substrate materials, including readily reclaimable and/or readily recyclable materials. There may be sustainability advantages in selecting readily reclaimable and recyclable materials for the substrate layers, however it may be appreciated that materials that are not readily recyclable or reclaimable may also be selected for the substrate materials. In various aspects, the substrate materials can include, for example, thermosetting plastic materials; thermoplastic materials (i.e. thermoplastic polymers), such as, for example, thermoplastic polyurethane (TPU), high density polyethylene (HDPE), polyethylene terephthalate (PET), polyvinyl chloride (PVC), low density polyethylene (LDPE), polypropylene (PP), polystyrene (PS); fabrics; wood; paper; or other insulating materials; or a combination thereof. The substrate material may exhibit an adhesive property at ambient conditions in a manufacturing environment, or it may exhibit an adhesive property once activated, e.g., by heating or by exposure to activator such as a solvent or other chemical, or by introducing the substrate material into a particular environment that renders it adhesive.

Electric components may be any electrical, electronic, electromechanical, and/or electric device or feature, such as, for example, an integrated circuit, semiconductors, transistor, diode, LED, capacitor, resistor, inductor, switch, terminal, connector, display, sensor, printed circuit board, or some other device or feature. In some aspects, the electric component may include a bare component. In some aspects, electrical component(s) may be partially or fully enclosed in various types of packages. In some aspects, where the electrical component 104 includes an integrated circuit and/or a semiconductor, a wide range of package types may be used, as described in detail below. For example, an electrical component may include one or more integrated circuits in the form of a bare die. As another example, the electrical component may include a die mounted to a substrate but not fully enclosed in a package, such as a chip-scale device.

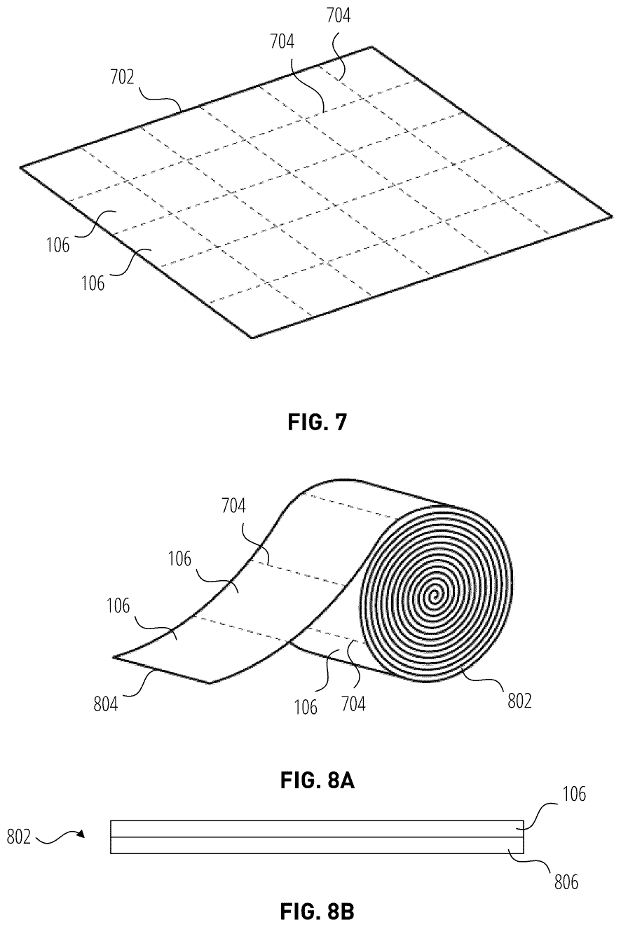

FIG. 7 illustrates a sheet 702 of thermal interface appliques 106, in an example embodiment. The thermal interface appliques 106 are illustrated abstractly. It is to be recognized and understood that while the description of the sheet 702 is with respect to the thermal interface applique 106, the principles disclosed may be applied to any thermal interface applique disclosed herein or that may be developed, as appropriate.

Each thermal interface applique 106 is partially separated from adjacent thermal interface appliques 106 by a perforation 704 or scoreline. In various examples, the perforation 704 is formed in the containment structure 110 (not depicted) of each thermal interface applique 106. In such an example, the sheet 702 may be formed with continuous containment structure 110 material and each thermal interface applique 106 formed by creating the perforation 704 within the containment structure 110, thereby creating separate thermal interface appliques 106. Each thermal interface applique 106 may be individually removed from the sheet 702 and utilized to adhere the electronic component 102 and heatsink 104 together and provide the thermal interface therebetween.

In an alternative example, the perforations 704 are not provided. In such an example, the containment structures 110 may be formed of continuous material and the thermal interface appliques 106 may not be fully separately identifiable while in the sheet 702. In such an example, a given thermal interface applique 106 may be cut out or otherwise separated from the sheet 702 by cutting through the containment structure 110, e.g., with shears, scissors, or any other suitable cutting instrument

FIG. 8A illustrates a roll 802 of thermal interface appliques 106, in an example embodiment. The thermal interface appliques 106 are illustrated abstractly. It is to be recognized and understood that while the description of the roll 802 is with respect to the thermal interface applique 106, the principles disclosed may be applied to any thermal interface applique disclosed herein or that may be developed, as appropriate.

As with the sheet 702 of FIG. 7, each thermal interface applique 106 is partially separated from adjacent thermal interface appliques 106 by a perforation 704, e.g., in the containment structure 110 (not depicted) of each thermal interface applique 106. Each thermal interface applique 106 may be individually removed from the roll 802, e.g., in sequence starting from an exposed end 804 of the roll 802. Alternatively, the perforations 704 mat not be provided and each thermal interface applique 106 may be cut from the roll 802.

FIG. 8B illustrates a side profile of a portion of the roll 802, in an example embodiment. The roll 802 may incorporate one or more release layers 806 positioned on at least one major surface of some or all of the thermal interface appliques 106 of the roll 802. The release layer may be a removable sheet that partially or removably adheres to the thermal interface applique 106 and may prevent or inhibit one thermal interface applique 106 in the roll 802 from coming into contact with another thermal interface applique 106 of the roll 802. Contact between thermal interface appliques 106 in the roll 802 may over time cause the material of the containment structure 110 of each thermal interface appliques 106 to flow together or otherwise cause the containment structures 110 to become fully or partially adhered to one another. The release layer 806 may also reduce or eliminate migration of the conductive gel 108 (not depicted) of the thermal interface appliques 106. While the release layer 806 may have particular relevance to the example of the roll 802, it is to be recognized and understood that one or more release layers 806 may also be applied to the sheet 702 of FIG. 7.

The release layer 806 may be formed from a readily recyclable

material. Although siliconized films have been long regarded as difficult to recycle, recent advancements have made recycling of thermoplastic or paper-based films treated with a silicone additive to enhance release. One such method is disclosed in U.S. Pat. No. 8,845,840, which is incorporated herein by reference in its entirety. In such examples, the optional release layer 806 may be selected from a group of readily recyclable materials, e.g., siliconized or non-siliconized PET film, or a paper-based release film (siliconized or non-siliconized).

As used herein, the term “conductive gel” or “deformable conductive material” may refer to a material such as those disclosed in the aforementioned International Patent Application No. PCT/US2017/019762 titled LIQUID WIRE, which was filed on Feb. 27, 2017 and published on Sep. 8, 2017 as International Patent Publication No. WO2017/151523A1, the disclosure of which is herein incorporated by reference in its entirety. For example, a deformable conductive material can include a variety of forms, such as a liquid, a paste, a gel, and/or a powder, amongst others, that has a deformable (e.g., soft, flexible, stretchable, bendable, elastic, flowable viscoelastic, Newtonian, non-Newtonian, etc.) quality.

In various aspects, a deformable conductive material can include an electroactive material, such as a deformable conductor produced from a conductive gel (e.g., made from a gallium indium alloy). The conductive gel can have a shear thinning composition and, according to some aspects, can include a mixture of materials in a desired ratio. The electrically conductive compositions, such as conductive gels, comprised in the articles described herein can, for example, have a paste like or gel consistency that can be created by taking advantage of, among other things, the structure that gallium oxide can impart on the compositions when gallium oxide is mixed into a eutectic gallium alloy. When mixed into a eutectic gallium alloy, gallium oxide can form micro or nanostructures that are further described herein, which structures are capable of altering the bulk material properties of the eutectic gallium alloy.

The electrically conductive compositions, such as conductive gels, comprised in the articles described herein can, for example, have a paste like or gel consistency that can be created by taking advantage of, among other things, the structure that gallium oxide can impart on the compositions when gallium oxide is mixed into a eutectic gallium alloy. When mixed into a eutectic gallium alloy, gallium oxide can form micro or nanostructures that are further described herein, which structures are capable of altering the bulk material properties of the eutectic gallium alloy.

As used herein, the term “eutectic” generally refers to a mixture of two or more phases of a composition that has the lowest melting point, and where the phases simultaneously crystallize from molten solution at this temperature. The ratio of phases to obtain a eutectic is identified by the eutectic point on a phase diagram. One of the features of eutectic alloys is their sharp melting point.

The electrically conductive compositions can be characterized as conducting shear thinning gel compositions. The electrically conductive compositions described herein can also be characterized as compositions having the properties of a Bingham plastic. For example, the electrically conductive compositions can be viscoplastics, such that they are rigid and capable of forming and maintaining three-dimensional features characterized by height and width at low stresses but flow as viscous fluids at high stress. Thus, for example, the electrically conductive compositions can have a viscosity ranging from about 10,000,000 Pa*s to about 40,000,000 Pa*s under low shear and about 150 Pa*s to 180 Pa*s at high shear. For example, under condition of low shear the composition has a viscosity of about 10,000,000 Pa*S, about 15,000,000 Pa*s, about 20,000,000 Pa*s, about 25,000,000 Pa*s, about 30,000,000 Pa*s, about 45,000,000 Pa*s, or about 40,000,000 Pa*s under conditions of low shear. Under condition of high shear, the composition has a viscosity of about 150 Pa*s, about 155 Pa*s, about 160 Pa*s, 165 Pa*s, about 170 Pa*s, about 175 Pa*s, or about 180 Pa*s.

The electrically conductive compositions described herein can have any suitable conductivity, such as a conductivity of from about 2×10⁵ S/m to about 8×10⁵ S/m.

The electrically conductive compositions described herein can have ay suitable melting point, such as a melting point of from about −20° C. to about 10° C., about −10° C. to about 5° C., about −5° C. to about 5° C. or about −5° C. to about 0° C.

The electrically conductive compositions can comprise a mixture of a eutectic gallium alloy and gallium oxide, wherein the mixture of eutectic gallium alloy and gallium oxide has a weight percentage (wt %) of between about 59.9% and about 99.9% eutectic gallium alloy, such as between about 67% and about 90%, and a wt % of between about 0.1% and about 2.0% gallium oxide such as between about 0.2 and about 1%. For example, the electrically conductive compositions can have about 60%, about 61%, about 62%, about 63%, about 64%, about 65%, about 66%, about 67%, about 68%, about 69%, about 70%, about 71%, about 72%, about 73%, about 74%, about 75%, about 76%, about 77%, about 78%, about 79%, about 80%, about 81%, about 82%, about 83%, about 84%, about 85%, about 86%, about 87%, about 88%, about 89%, about 90%, about 91%, about 92%, about 93%, about 94%, about 95%, about 96%, about 97%, about 98%, about 99%, or greater, such as about 99.9% eutectic gallium alloy, and about 0.1%, about 0.2%, about 0.3%, about 0.4%, about 0.5%, about 0.6%, about 0.7%, about 0.8%, about 0.9%, about 1.0%, about 1.1%, about 1.2%, about 1.3%, about 1.4%, about 1.5%, about 1.6%, about 1.7%, about 1.8%, about 1.9%, and about 2.0% gallium oxide.

The eutectic gallium alloy can include gallium-indium or gallium-indium-tin in any ratio of elements. For example, a eutectic gallium alloy includes gallium and indium. The electrically conductive compositions can have any suitable percentage of gallium by weight in the gallium-indium alloy that is between about 40% and about 95%, such as about 40%, about 41%, about 42%, about 43%, about 44%, about 45%, about 46%, about 47%, about 48%, about 49%, about 50%, about 51%, about 52%, about 53%, about 54%, about 55%, about 56%, about 57%, about 58%, about 59%, about 60%, about 61%, about 62%, about 63%, about 64%, about 65%, about 66%, about 67%, about 68%, about 69%, about 70%, about 71%, about 72%, about 73%, about 74%, about 75%, about 76%, about 77%, about 78%, about 79%, about 80%, about 81%, about 82%, about 83%, about 84%, about 85%, about 86%, about 87%, about 88%, about 89%, about 90%, about 91%, about 92%, about 93%, about 94%, or about 95%.

The electrically conductive compositions can have a percentage of indium by weight in the gallium-indium alloy that is between about 5% and about 60%, such as about 5%, about 6%, about 7%, about 8%, about 9%, about 10%, about 11%, about 12%, about 13%, about 14%, about 15%, about 16%, about 17%, about 18%, about 19%, about 20%, about 21%, about 22%, about 23%, about 24%, about 25%, about 26%, about 27%, about 28%, about 29%, about 30%, about 31%, about 32%, about 33%, about 34%, about 35%, about 36%, about 37%, about 38%, about 39%, about 40%, about 41%, about 42%, about 43%, about 44%, about 45%, about 46%, about 47%, about 48%, about 49%, about 50%, about 51%, about 52%, about 53%, about 54%, about 55%, about 56%, about 57%, about 58%, about 59%, or about 60%.

The eutectic gallium alloy can include gallium and tin. For example, the electrically conductive compositions can have a percentage of tin by weight in the alloy that is between about 0.001% and about 50%, such as about 0.001%, about 0.005%, about 0.01%, about 0.05%, about 0.1%, about 0.2%, about 0.3%, about 0.4%, about 0.5%, about 0.6%, about 0.7%, about 0.8%, about 0.9%, about 1%, about 1.5%, about 2%, about 3%, about 4%, about 5%, about 6%, about 7%, about 8%, about 9%, about 10%, about 11%, about 12%, about 13%, about 14%, about 15%, about 16%, about 17%, about 18%, about 19%, about 20%, about 21%, about 22%, about 23%, about 24%, about 25%, about 26%, about 27%, about 28%, about 29%, about 30%, about 31%, about 32%, about 33%, about 34%, about 35%, about 36%, about 37%, about 38%, about 39%, about 40%, about 41%, about 42%, about 43%, about 44%, about 45%, about 46%, about 47%, about 48%, about 49%, or about 50%.

The electrically conductive compositions can comprise one or more micro-particles or sub-micron scale particles blended with the eutectic gallium alloy and gallium oxide. The particles can be suspended, either coated in eutectic gallium alloy or gallium and encapsulated in gallium oxide or not coated in the previous manner, within eutectic gallium alloy. The micro-or sub-micron scale particles can range in size from nanometer to micrometer and can be suspended in gallium, gallium-indium alloy, or gallium-indium-tin alloy. Particle to alloy ratio can vary and can change the flow properties of the electrically conductive compositions. The micro and nanostructures can be blended within the electrically conductive compositions through sonication or other suitable means. The electrically conductive compositions can include a colloidal suspension of micro and nanostructures within the eutectic gallium alloy/gallium oxide mixture.

The electrically conductive compositions can further include one or more micro-particles or sub-micron scale particles dispersed within the compositions. This can be achieved in any suitable way, including by suspending particles, either coated in eutectic gallium alloy or gallium and encapsulated in gallium oxide or not coated in the previous manner, within the electrically conductive compositions or, specifically, within the eutectic gallium alloy fluid. These particles can range in size from nanometer to micrometer and can be suspended in gallium, gallium-indium alloy, or gallium-indium-tin alloy. Particle to alloy ratio can vary, in order to, among other things, change fluid properties of at least one of the alloys and the electrically conductive compositions. In addition, the addition of any ancillary material to colloidal suspension or cutectic gallium alloy in order to, among other things, enhance or modify its physical, electrical or thermal properties. The distribution of micro and nanostructures within the at least one of the eutectic gallium alloy and the electrically conductive compositions can be achieved through any suitable means, including sonication or other mechanical means without the addition of particles. In certain embodiments, the one or more micro-particles or sub-micron particles are blended with the at least one of the eutectic gallium alloy and the electrically conductive compositions with wt % of between about 0.001% and about 40.0% of micro-particles, for example about 0.001%, about 0.005%, about 0.01%, about 0.05%, about 0.1%, about 0.2%, about 0.3%, about 0.4%, about 0.5%, about 0.6%, about 0.7%, about 0.8%, about 0.9%, about 1%, about 1.5%, about 2%, about 3%, about 4%, about 5%, about 6%, about 7%, about 8%, about 9%, about 10%, about 11%, about 12%, about 13%, about 14%, about 15%, about 16%, about 17%, about 18%, about 19%, about 20%, about 21%, about 22%, about 23%, about 24%, about 25%, about 26%, about 27%, about 28%, about 29%, about 30%, about 31%, about 32%, about 33%, about 34%, about 35%, about 36%, about 37%, about 38%, about 39%, or about 40.

The one or more micro-or sub-micron particles can be made of any suitable material including soda glass, silica, borosilicate glass, quartz, oxidized copper, silver coated copper, non-oxidized copper, tungsten, super saturated tin granules, glass, graphite, silver coated copper, such as silver coated copper spheres, and silver coated copper flakes, copper flakes, or copper spheres, or a combination thereof, or any other material that can be wetted by the at least one of the eutectic gallium alloy and the electrically conductive compositions. The one or more micro-particles or sub-micron scale particles can have any suitable shape, including the shape of spheroids, rods, tubes, a flakes, plates, cubes, prismatic, pyramidal, cages, and dendrimers. The one or more micro-particles or sub-micron scale particles can have any suitable size, including a size range of about 0.5 microns to about 60 microns, as about 0.5 microns, about 0.6 microns, about 0.7 microns, about 0.8 microns, about 0.9 microns, about 1 microns, about 1.5 microns, about 2 microns, about 3 microns, about 4 microns, about 5 microns, about 6 microns, about 7 microns, about 8 microns, about 9 microns, about 10 microns, about 11 microns, about 12 microns, about 13 microns, about 14 microns, about 15 microns, about 16 microns, about 17 microns, about 18 microns, about 19 microns, about 20 microns, about 21 microns, about 22 microns, about 23 microns, about 24 microns, about 25 microns, about 26 microns, about 27 microns, about 28 microns, about 29 microns, about 30 microns, about 31 microns, about 32 microns, about 33 microns, about 34 microns, about 35 microns, about 36 microns, about 37 microns, about 38 microns, about 39 microns, about 40 microns, about 41 microns, about 42 microns, about 43 microns, about 44 microns, about 45 microns, about 46 microns, about 47 microns, about 48 microns, about 49 microns, about 50 microns, about 51 microns, about 52 microns, about 53 microns, about 54 microns, about 55 microns, about 56 microns, about 57 microns, about 58 microns, about 59 microns, or about 60 microns.

The electrically conductive compositions described herein can be made by any suitable method, including a method comprising blending surface oxides formed on a surface of a eutectic gallium alloy into the bulk of the eutectic gallium alloy by shear mixing of the surface oxide/alloy interface. Shear mixing of such compositions can induce a cross linked microstructure in the surface oxides; thereby forming a conducting shear thinning gel composition. A colloidal suspension of micro-structures can be formed within the eutectic gallium alloy/gallium oxide mixture, for example as, gallium oxide particles and/or sheets.

The surface oxides can be blended in any suitable ratio, such as at a ratio of between about 59.9% (by weight) and about 99.9% eutectic gallium alloy, to about 0.1% (by weight) and about 2.0% gallium oxide. For example percentage by weight of gallium alloy blended with gallium oxide is about 60%, 61%, about 62%, about 63%, about 64%, about 65%, about 66%, about 67%, about 68%, about 69%, about 70%, about 71%, about 72%, about 73%, about 74%, about 75%, about 76%, about 77%, about 78%, about 79%, about 80%, about 81%, about 82%, about 83%, about 84%, about 85%, about 86%, about 87%, about 88%, about 89%, about 90%, about 91%, about 92%, about 93%, about 94%, about 95%, about 96%, about 97%, about 98%, about 99%, or greater, such as about 99.9% eutectic gallium alloy while the weight percentage of gallium oxide is about 0.1%, about 0.2%, about 0.3%, about 0.4%, about 0.5%, about 0.6%, about 0.7%, about 0.8%, about 0.9%, about 1.0%, about 1.1%, about 1.2%, about 1.3%, about 1.4%, about 1.5%, about 1.6%, about 1.7%, about 1.8%, about 1.9%, and about 2.0% gallium oxide. In embodiments, the eutectic gallium alloy can include gallium-indium or gallium-indium-tin in any ratio of the recited elements. For example, a eutectic gallium alloy can include gallium and indium.

The weight percentage of gallium in the gallium-indium alloy can be between about 40% and about 95%, such as about 40%, about 41%, about 42%, about 43%, about 44%, about 45%, about 46%, about 47%, about 48%, about 49%, about 50%, about 51%, about 52%, about 53%, about 54%, about 55%, about 56%, about 57%, about 58%, about 59%, about 60%, about 61%, about 62%, about 63%, about 64%, about 65%, about 66%, about 67%, about 68%, about 69%, about 70%, about 71%, about 72%, about 73%, about 74%, about 75%, about 76%, about 77%, about 78%, about 79%, about 80%, about 81%, about 82%, about 83%, about 84%, about 85%, about 86%, about 87%, about 88%, about 89%, about 90%, about 91%, about 92%, about 93%, about 94%, or about 95%.

Alternatively or in addition, the weight percentage of indium in the gallium-indium alloy can be between about 5% and about 60%, such as about 5%, about 6%, about 7%, about 8%, about 9%, about 10%, about 11%, about 12%, about 13%, about 14%, about 15%, about 16%, about 17%, about 18%, about 19%, about 20%, about 21%, about 22%, about 23%, about 24%, about 25%, about 26%, about 27%, about 28%, about 29%, about 30%, about 31%, about 32%, about 33%, about 34%, about 35%, about 36%, about 37%, about 38%, about 39%, about 40%, about 41%, about 42%, about 43%, about 44%, about 45%, about 46%, about 47%, about 48%, about 49%, about 50%, about 51%, about 52%, about 53%, about 54%, about 55%, about 56%, about 57%, about 58%, about 59%, or about 60%.

A eutectic gallium alloy can include gallium, indium, and tin. The weight percentage of tin in the gallium-indium-tin alloy can be between about 0.001% and about 50%, such as about 0.001%, about 0.005%, about 0.01%, about 0.05%, about 0.1%, about 0.2%, about 0.3%, about 0.4%, about 0.5%, about 0.6%, about 0.7%, about 0.8%, about 0.9%, about 1%, about 1.5%, about 2%, about 3%, about 4%, about 5%, about 6%, about 7%, about 8%, about 9%, about 10%, about 11%, about 12%, about 13%, about 14%, about 15%, about 16%, about 17%, about 18%, about 19%, about 20%, about 21%, about 22%, about 23%, about 24%, about 25%, about 26%, about 27%, about 28%, about 29%, about 30%, about 31%, about 32%, about 33%, about 34%, about 35%, about 36%, about 37%, about 38%, about 39%, about 40%, about 41%, about 42%, about 43%, about 44%, about 45%, about 46%, about 47%, about 48%, about 49%, or about 50%.

The weight percentage of gallium in the gallium-indium-tin alloy can be between about 40% and about 95%, such as about 40%, about 41%, about 42%, about 43%, about 44%, about 45%, about 46%, about 47%, about 48%, about 49%, about 50%, about 51%, about 52%, about 53%, about 54%, about 55%, about 56%, about 57%, about 58%, about 59%, about 60%, about 61%, about 62%, about 63%, about 64%, about 65%, about 66%, about 67%, about 68%, about 69%, about 70%, about 71%, about 72%, about 73%, about 74%, about 75%, about 76%, about 77%, about 78%, about 79%, about 80%, about 81%, about 82%, about 83%, about 84%, about 85%, about 86%, about 87%, about 88%, about 89%, about 90%, about 91%, about 92%, about 93%, about 94%, or about 95%.

Alternatively or in addition, the weight percentage of indium in the gallium-indium-tin alloy can be between about 5% and about 60%, such as about 5%, about 6%, about 7%, about 8%, about 9%, about 10%, about 11%, about 12%, about 13%, about 14%, about 15%, about 16%, about 17%, about 18%, about 19%, about 20%, about 21%, about 22%, about 23%, about 24%, about 25%, about 26%, about 27%, about 28%, about 29%, about 30%, about 31%, about 32%, about 33%, about 34%, about 35%, about 36%, about 37%, about 38%, about 39%, about 40%, about 41%, about 42%, about 43%, about 44%, about 45%, about 46%, about 47%, about 48%, about 49%, about 50%, about 51%, about 52%, about 53%, about 54%, about 55%, about 56%, about 57%, about 58%, about 59%, or about 60%.

One or more micro-particles or sub-micron scale particles can be blended with the eutectic gallium alloy and gallium oxide. For example, the one or more micro-particles or sub-micron particles can be blended with the mixture with wt % of between about 0.001% and about 40.0% of micro-particles in the composition, for example about 0.001%, about 0.005%, about 0.01%, about 0.05%, about 0.1%, about 0.2%, about 0.3%, about 0.4%, about 0.5%, about 0.6%, about 0.7%, about 0.8%, about 0.9%, about 1%, about 1.5%, about 2%, about 3%, about 4%, about 5%, about 6%, about 7%, about 8%, about 9%, about 10%, about 11%, about 12%, about 13%, about 14%, about 15%, about 16%, about 17%, about 18%, about 19%, about 20%, about 21%, about 22%, about 23%, about 24%, about 25%, about 26%, about 27%, about 28%, about 29%, about 30%, about 31%, about 32%, about 33%, about 34%, about 35%, about 36%, about 37%, about 38%, about 39%, or about 40. In embodiments the particles can be soda glass, silica, borosilicate glass, quartz, oxidized copper, silver coated copper, non-oxidized copper, tungsten, super saturated tin granules, glass, graphite, silver coated copper, such as silver coated copper spheres, and silver coated copper flakes, copper flakes or copper spheres or a combination thereof, or any other material that can be wetted by gallium. In some embodiments the one or more micro-particles or sub-micron scale particles are in the shape of spheroids, rods, tubes, a flakes, plates, cubes, prismatic, pyramidal, cages, and dendrimers. In certain embodiments, the one or more micro-particles or sub-micron scale particles are in the size range of about 0.5 microns to about 60 microns, as about 0.5 microns, about 0.6 microns, about 0.7 microns, about 0.8 microns, about 0.9 microns, about 1 microns, about 1.5 microns, about 2 microns, about 3 microns, about 4 microns, about 5 microns, about 6 microns, about 7 microns, about 8 microns, about 9 microns, about 10 microns, about 11 microns, about 12 microns, about 13 microns, about 14 microns, about 15 microns, about 16 microns, about 17 microns, about 18 microns, about 19 microns, about 20 microns, about 21 microns, about 22 microns, about 23 microns, about 24 microns, about 25 microns, about 26 microns, about 27 microns, about 28 microns, about 29 microns, about 30 microns, about 31 microns, about 32 microns, about 33 microns, about 34 microns, about 35 microns, about 36 microns, about 37 microns, about 38 microns, about 39 microns, about 40 microns, about 41 microns, about 42 microns, about 43 microns, about 44 microns, about 45 microns, about 46 microns, about 47 microns, about 48 microns, about 49 microns, about 50 microns, about 51 microns, about 52 microns, about 53 microns, about 54 microns, about 55 microns, about 56 microns, about 57 microns, about 58 microns, about 59 microns, or about 60 microns.

In various aspects, the conductive gel 108 material may exhibit adhesion to various layers of a circuit assembly and terminal/contacts of an electric component, as determined by the “Smear Test.” The Smear Test may be performed by smearing approximately 1 cm³ of a deformable conductive material on a test coupon of the layer material or the terminal/contact material. The conductive gel 108 material is smeared with a cotton swab (i.e., a Q-Tip™) across the test coupon. If the conductive gel 108 material coats the test coupon without void formation, then the conductive gel 108 material exhibits adhesion to the test coupon material. Conversely, if smearing the conductive gel 108 material to the test coupon causes the conductive gel 108 material to bead, thereby leaving voids on the test coupon, then the conductive gel 108 material does not exhibit adhesion. For example, some formulations of conductive gel 108 materials may have a surface tension that causes the deformable conductive material to bead. The Smear Test should be performed for all materials that have contact interfaces with the deformable conductive material to test for adhesion (e.g., terminals, channels, leads, contact point walls, etc.).

In various aspects, a deformable conductive material can be a non-hazardous material. As used herein, the term “non-hazardous” can mean that a material is RoHS (Restriction of Hazardous Substances) complaint according to European Union Directive 2002/95/EC, Directive 2011/65/EU, and/or Directive 2015/863 (i.e. RoHS, RoHS 2, RoHS 3). For example, in some aspects, a non-hazardous material can include a wt. % of less than 0.01% Cadmium (Cd), less than 0.1% Lead (Pb), less than 0.1% Mercury (Hg), less than 0.1% Hexavalent Chromium (Cr VI), less than 0.1% Polybrominated Biphenyls (PBB), less than 0.1% Polybrominated Diphenyl Ethers (PBDE), less than 0.1% Bis(2-Ethylhexyl) phthalate (DEHP), less than 0.1% Benzyl butyl phthalate (BBP), less than 0.1% Dibutyl phthalate (DBP), and less than 0.1% Diisobutyl phthalate (DIBP).

### EXAMPLES

Example 1 is a thermal interface applique, comprising: a containment structure having an adhesive property and a first thermal coefficient; and conductive gel, contained within at least one opening in the containment structure, having a second thermal coefficient at least ten times greater than the first thermal coefficient; wherein the conductive gel is configured to thermally couple a heat source to a heatsink; wherein the adhesive property of the containment structure is configured to adhere at least one of the heat source and the heatsink to the containment structure.

In Example 2, the subject matter of Example 1 includes, wherein the conductive gel is completely surrounded by the containment structure to inhibit lateral migration of the conductive gel from the containment structure.

In Example 3, the subject matter of any one or more of Examples 1 and 2 includes, wherein the opening conforms to a form factor of the heat source.

In Example 4, the subject matter of any one or more of Examples 1-3 includes, wherein a surface area of the conductive gel is at least fifty (50) percent that of a surface area of the heat source.

In Example 5, the subject matter of any one or more of Examples 1-4 includes, wherein the opening is one of a plurality of openings separated by portions of the containment structure, wherein each of the plurality of openings contains some of the conductive gel.

In Example 6, the subject matter of any one or more of Examples 1-5 includes, wherein the plurality of openings are of common shapes.

In Example 7, the subject matter of any one or more of Examples 1-6 includes, wherein the plurality of openings are of differing shapes.

In Example 8, the subject matter of any one or more of Examples 1-7 includes, wherein the plurality of openings are of regular shapes.

In Example 9, the subject matter of any one or more of Examples 1-8 includes, wherein at least one of the plurality of openings is an irregular shape.

In Example 10, the subject matter of any one or more of Examples 1-9 includes, wherein the containment structure is comprised of a thermoplastic polyurethane.

In Example 11, the subject matter of any one or more of Examples 1-10 includes, wherein the containment structure is comprised of at least one of: a thermoset epoxy-based film and a C-stage resin film.

In Example 12, the subject matter of any one or more of Examples 1-11 includes, wherein the containment structure comprises an adhesive film that provides the adhesive property.

In Example 13, the subject matter of any one or more of Examples 1-12 includes, a release layer on at least one major surface of the containment structure, the release layer configured to be removed to expose the adhesive property.

Example 14 is a system, comprising: a heat source; a heatsink; and a thermal interface applique, comprising: a containment structure having an adhesive property and a first thermal coefficient; and conductive gel, contained within at least one opening in the containment structure, having a second thermal coefficient at least ten times greater than the first thermal coefficient; wherein the conductive gel is configured to thermally couple a heat source to a heatsink; wherein the adhesive property of the containment structure is configured to adhere at least one of the heat source and the heatsink to the containment structure.

In Example 15, the subject matter of Example 14 includes, wherein the heat source is an electronic component.

In Example 16, the subject matter of any one or more of Examples 14 and 15 includes, wherein the conductive gel is completely surrounded by the containment structure to inhibit lateral migration of the conductive gel from the containment structure.

In Example 17, the subject matter of any one or more of Examples 14-16 includes, wherein the opening conforms to a form factor of the heat source.

In Example 18, the subject matter of any one or more of Examples 14-17 includes, wherein a surface area of the conductive gel is at least fifty (50) percent that of a surface area of the heat source.

In Example 19, the subject matter of any one or more of Examples 14-18 includes, wherein the opening is one of a plurality of openings separated by portions of the containment structure, wherein each of the plurality of openings contains some of the conductive gel.

In Example 20, the subject matter of any one or more of Examples 14-19 includes, wherein the plurality of openings are of common shapes.

In Example 21, the subject matter of any one or more of Examples 14-20 includes, wherein the plurality of openings are of differing shapes.

In Example 22, the subject matter of any one or more of Examples 14-21 includes, wherein the plurality of openings are of regular shapes.

In Example 23, the subject matter of any one or more of Examples 14-22 includes, wherein at least one of the plurality of openings is an irregular shape.

In Example 24, the subject matter of any one or more of Examples 14-23 includes, wherein the containment structure is comprised of a thermoplastic polyurethane.

In Example 25, the subject matter of any one or more of Examples 14-24 includes, wherein the containment structure is comprised of at least one of: a thermoset epoxy-based film and a C-stage resin film.

In Example 26, the subject matter of any one or more of Examples 14-25 includes, wherein the containment structure comprises an adhesive film that provides the adhesive property.

In Example 27, the subject matter of any one or more of Examples 14-26 includes, a release layer on at least one major surface of the containment structure, the release layer configured to be removed to expose the adhesive property.

Example 28 is at least one machine-readable medium including instructions that, when executed by processing circuitry, cause the processing circuitry to perform operations to implement of any of Examples 1-27.

Example 29 is an apparatus comprising means to implement of any of Examples 1-27.

Example 30 is a system to implement of any of Examples 1-27.

Example 31 is a method to implement of any of Examples 1-27.

Some portions of this specification are presented in terms of algorithms or symbolic representations of operations on data stored as bits or binary digital signals within a machine memory (e.g., a computer memory). These algorithms or symbolic representations are examples of techniques used by those of ordinary skill in the data processing arts to convey the substance of their work to others skilled in the art. As used herein, an “algorithm” is a self-consistent sequence of operations or similar processing leading to a desired result. In this context, algorithms and operations involve physical manipulation of physical quantities. Typically, but not necessarily, such quantities may take the form of electrical, magnetic, or optical signals capable of being stored, accessed, transferred, combined, compared, or otherwise manipulated by a machine. It is convenient at times, principally for reasons of common usage, to refer to such signals using words such as “data,” “content,” “bits,” “values,” “elements,” “symbols,” “characters,” “terms,” “numbers,” “numerals,” or the like. These words, however, are merely convenient labels and are to be associated with appropriate physical quantities.

Unless specifically stated otherwise, discussions herein using words such as “processing,” “computing,” “calculating,” “determining,” “presenting,” “displaying,” or the like may refer to actions or processes of a machine (e.g., a computer) that manipulates or transforms data represented as physical (e.g., electronic, magnetic, or optical) quantities within one or more memories (e.g., volatile memory, non-volatile memory, or any suitable combination thereof), registers, or other machine components that receive, store, transmit, or display information. Furthermore, unless specifically stated otherwise, the terms “a” or “an” are herein used, as is common in patent documents, to include one or more than one instance. Finally, as used herein, the conjunction “or” refers to a non-exclusive “or,” unless specifically stated otherwise.

What is claimed is:

1. A thermal interface applique, comprising:
a containment structure having an adhesive property and a first thermal coefficient; and
conductive gel, contained within at least one opening in the containment structure, having a second thermal coefficient at least ten times greater than the first thermal coefficient;
wherein the conductive gel is configured to thermally couple a heat source to a heatsink;
wherein the adhesive property of the containment structure is configured to adhere at least one of the heat source and the heatsink to the containment structure.

2. The thermal interface applique of claim 1, wherein the conductive gel is completely surrounded by the containment structure to inhibit lateral migration of the conductive gel from the containment structure.

3. The thermal interface applique of claim 2, wherein the opening conforms to a form factor of the heat source.

4. The thermal interface applique of claim 3, wherein a surface area of the conductive gel is at least fifty (50) percent that of a surface area of the heat source.

5. The thermal interface applique of claim 3, wherein the opening is one of a plurality of openings separated by portions of the containment structure, wherein each of the plurality of openings contains some of the conductive gel.

6. The thermal interface applique of claim 1, wherein the containment structure is comprised of a thermoplastic polyurethane.

7. The thermal interface applique of claim 1, wherein the containment structure is comprised of at least one of: a thermoset epoxy-based film and a C-stage resin film.

8. The thermal interface applique of claim 1, wherein the containment structure comprises an adhesive film that provides the adhesive property.

9. The thermal interface applique of claim 1, further comprising a release layer on at least one major surface of the containment structure, the release layer configured to be removed to expose the adhesive property.

10. A system, comprising:
a heat source;
a heatsink; and
a thermal interface applique, comprising:
a containment structure having an adhesive property and a first thermal coefficient; and
conductive gel, contained within at least one opening in the containment structure, having a second thermal coefficient at least ten times greater than the first thermal coefficient;
wherein the conductive gel is configured to thermally couple a heat source to a heatsink;
wherein the adhesive property of the containment structure is configured to adhere at least one of the heat source and the heatsink to the containment structure.

11. The system of claim 10, wherein the heat source is an electronic component.

12. The system of claim 10, wherein the conductive gel is completely surrounded by the containment structure to inhibit lateral migration of the conductive gel from the containment structure.

13. The system of claim 12, wherein the opening conforms to a form factor of the heat source.

14. The system of claim 13, wherein a surface area of the conductive gel is at least fifty (50) percent that of a surface area of the heat source.

15. The system of claim 13, wherein the opening is one of a plurality of openings separated by portions of the containment structure, wherein each of the plurality of openings contains some of the conductive gel.

16. The system of claim 10, wherein the containment structure is comprised of a thermoplastic polyurethane.

17. The system of claim 10, wherein the containment structure is comprised of at least one of: a thermoset epoxy-based film and a C-stage resin film.

18. The system of claim 10, wherein the containment structure comprises an adhesive film that provides the adhesive property.

19. The system of claim 10, further comprising a release layer on at least one major surface of the containment structure, the release layer configured to be removed to expose the adhesive property.
